(19) United States
(12) Patent Application Publication
(10) Pub. No.: US 2024/0096698 A1
(43) Pub. Date: Mar. 21, 2024

(54) SELECTIVE TUNGSTEN CONTACT PLUGS ABOVE GATE AND SOURCE/DRAIN CONTACTS

(71) Applicant: QUALCOMM Incorporated, San Diego, CA (US)

(72) Inventors: Junjing BAO, San Diego, CA (US); Chih-Sung YANG, Hsinchu City (TW); Haining YANG, San Diego, CA (US)

(21) Appl. No.: 17/933,683

(22) Filed: Sep. 20, 2022

(51) Int. Cl. H01L 21/768

(52) U.S. Cl. CPC H01L 21/76897; H01L 21/76816; H01L 21/76879; H01L 27/10855

(57) ABSTRACT

In an aspect, a transistor comprises a gate structure having a metal gate, a dielectric layer at least partially surrounding the metal gate, a metal cap over a portion of the metal gate that is not surrounded by the dielectric layer, and a gate contact comprising tungsten in direct contact with the metal cap. In another aspect, a transistor comprises source, drain, and channel regions, a gate structure comprising a metal gate between gate spacers above the channel region, and a source or drain (S/D) contact structure. The S/D contact structure comprises an S/D barrier layer above at least a portion of the source or drain region and in direct contact with a gate spacer, and an S/D contact, comprising a first portion above the S/D barrier layer; and a second portion comprising tungsten, above the first portion.

### BACKGROUND OF THE DISCLOSURE

### 1. Field of the Disclosure

Aspects of the disclosure relate generally to wafer fabrication methods, and more specifically, but not exclusively, to selective tungsten contact plugs above gate and source/drain contacts and fabrication techniques thereof.

### 2. Description of the Related Art

Wafer fabrication techniques involve the layering of different materials atop a substrate material to create transistors, resistors, capacitors, and more complex structures, referred to herein as “devices,” as well as the electrical interconnections between them. The devices and interconnections are formed using a variety of wafer process techniques, including diffusing or embedding ions into an otherwise neutral substrate, depositing one material over another using chemical vapor deposition (CVD), depositing metal using sputtering techniques, causing oxides to grow in a furnace in the presence of oxygen, and causing selective growth of one material from a seed layer of the same or a similar material, to name a few.

A typical wafer cross section shows a substrate, transistors and other devices built in or on the substrate, and metal interconnection layers above the transistors and other devices, with insulating layers between devices, between devices and interconnection layers, and between interconnection layers. Electrical connections from one conducting layer to another conducting layer through the insulating layer separating the two are made using vertical connections called vias. A transistor, for example, comprises a source and drain separated by a gate that controls the flow of carriers between the source and drain. Electrical connections to the source, drain, and gate, typically involve vias from the source, drain, or gate to a metal interconnection layer above. An electrical connection to a source or drain region is referred to generically as a source/drain (S/D) contact, and an electrical connection to a gate is referred to generically as a gate contact. To make a via through an insulating layer, a hole is etched through the insulating layer, and the hole is then filled with metal. The metal that fills the hole may be referred to as a plug.

FIG. 1 illustrates a cross-sectional view of an example 100 of a conventional contact plug structure above gate and source/drain contacts. As shown in FIG. 1, wafer substrate 102 includes an epitaxial structure 104 that connects to a source or drain region 106, which may be referred to herein as a “source/drain region” or “S/D region.” S/D region 106 may be a source region or a drain region, and the contact structure thereon may be a source contact or a drain contact, which may be referred to herein as a “source/drain contact” or “S/D contact.”

Between pairs of S/D regions 106 are channel regions 108. In the example shown in FIG. 1, the S/D contact structure includes a S/D contact barrier layer 110, such as titanium nitride (TiN), that buffers the S/D contact 112 from the surrounding passivation material 114, such as silicon dioxide (SiO₂). The S/D contact 112 is conventionally tungsten (W) or cobalt (Co), and the S/D contact barrier layer 110 prevents the contact metal from diffusing into the passivation material 114.

FIG. 1 also shows cross-sections of two transistors, each transistor comprising a pair of gate spacers 116, between which is a gate structure comprising a metal gate 118 at least partially surrounded by a high-k material 120, such as hafnium oxide (HfO₂). An interfacial layer 122 separates the high-k material 120 from the wafer substrate 102. A dielectric etch stop layer 124, such as silicon oxycarbide (SiOC), separates the passivation material 114 from an upper passivation layer 126, which may be SiO₂.

As shown in FIG. 1, a tungsten contact plug 128 connects directly to the S/D contact 112 through a hole in the etch stop layer 124. As shown in FIG. 1, the gate contact 130 does not connect directly to the metal gate 118, but is separated from the metal gate 118 by a gate contact barrier layer 132, such as titanium (Ti) or TiN. The gate contact barrier layer 132 may increase the resistance of the gate contact 130, which may limit device performance. Selective tungsten cannot directly grow on metal gate surfaces such as TiN or TiAlC, which means that the tungsten gate contact cannot be a selective tungsten structure but must instead be created using chemical vapor deposition (CVD) and etching. Also, due to the relatively small size of the metal gate 118 (e.g., less than 10 nanometers (nm) in width), the gate contact barrier layer 132 has a relatively small contact area with the metal gate 118, which further increases resistance.

Accordingly, there is a need for contact plugs that overcome the deficiencies of conventional contact plugs, as well as methods for fabricating the same.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a transistor includes a gate structure, comprising: a metal gate; a dielectric layer at least partially surrounding the metal gate; a metal cap disposed over a portion of the metal gate that is not surrounded by the dielectric layer; and a gate contact comprising tungsten, disposed over, and in direct contact with, the metal cap.

In an aspect, a semiconductor structure includes a transistor, comprising: a source region; a drain region; a channel region, the channel region being disposed between the source region and the drain region; a gate structure disposed above the channel region, comprising a metal gate disposed between gate spacers; and a source or drain (S/D) contact structure, the S/D contact structure comprising: an S/D barrier layer disposed above at least a portion of the source region or the drain region, wherein at least a portion of the S/D barrier layer is in direct contact with one of the gate spacers; and an S/D contact, comprising a first portion disposed above the S/D barrier layer; and a second portion comprising tungsten, disposed above the first portion.

In an aspect, a method of fabricating a gate contact structure for a transistor includes etching a top portion of the metal gate to create a first recess within the gate spacers having a first depth; depositing a metal cap to substantially fill the first recess within the gate spacers; and forming selective tungsten above and in direct contact with the metal cap.

In an aspect, a method of fabricating a source or drain (S/D) contact structure for a transistor comprising a source region includes depositing a S/D barrier layer above at least a portion of the source region or the drain region, wherein at least a portion of the S/D barrier layer is in direct contact with one of the gate spacers; and depositing an S/D contact above the S/D barrier layer, wherein at least a portion of the S/D contact comprises selective tungsten.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 illustrates a cross-sectional view of an example of a conventional contact plug structure above gate and source/drain contacts.

FIG. 2A and FIG. 2B illustrate cross-sectional views of an example of a selective tungsten contact plug structure above gate and source/drain contacts, according to aspects of the disclosure.

FIGS. 3A through 3H are cross-sectional views illustrating fabrication techniques in accordance with one or more aspects of the disclosure.

FIG. 4A and FIG. 4B are flowcharts showing portions of an example process 400 associated with selective tungsten contact plugs above gate contacts, according to aspects of the disclosure.

FIG. 5 is a flowchart showing an example process 400 associated with selective tungsten contact plugs above source/drain contacts, according to aspects of the disclosure.

FIG. 6 illustrates an exemplary mobile device in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Semiconductor dies with selective tungsten contact plugs above gate and source/drain contacts (S/D), and methods for making the same, are herein disclosed. In an aspect, a transistor comprises a gate structure having a metal gate, a dielectric layer at least partially surrounding the metal gate, a metal cap over a portion of the metal gate that is not surrounded by the dielectric layer, and a gate contact comprising selective tungsten in direct contact with the metal cap. In another aspect, a transistor comprises source, drain, and channel regions, a gate structure comprising a metal gate between gate spacers above the channel region, and a source or drain (S/D) contact structure. The S/D contact structure comprises an S/D barrier layer above at least a portion of the source or drain region and in direct contact with a gate spacer, and an S/D contact, comprising a first portion above the S/D barrier layer; and a second portion comprising tungsten, above the first portion.

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

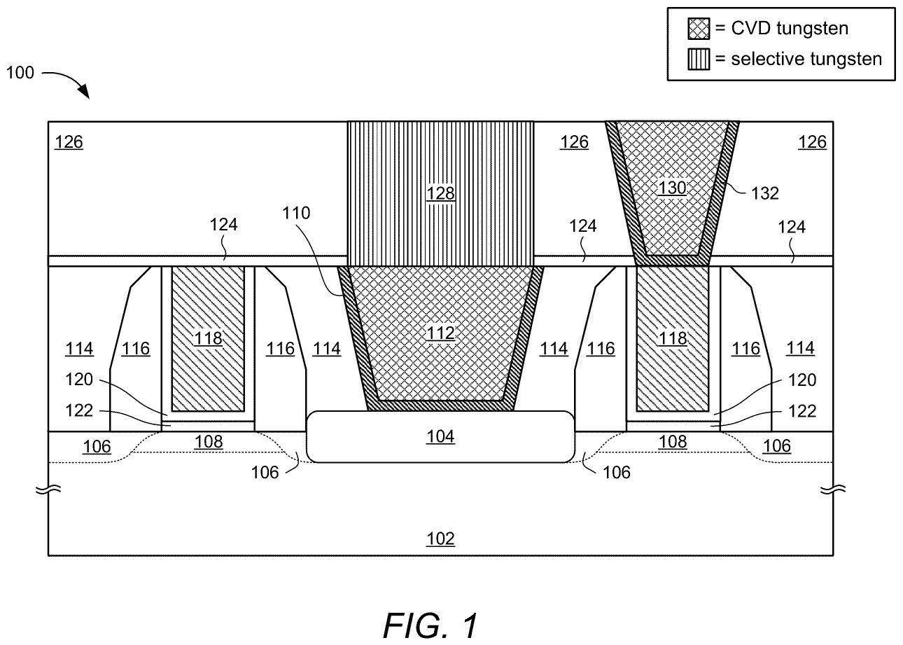

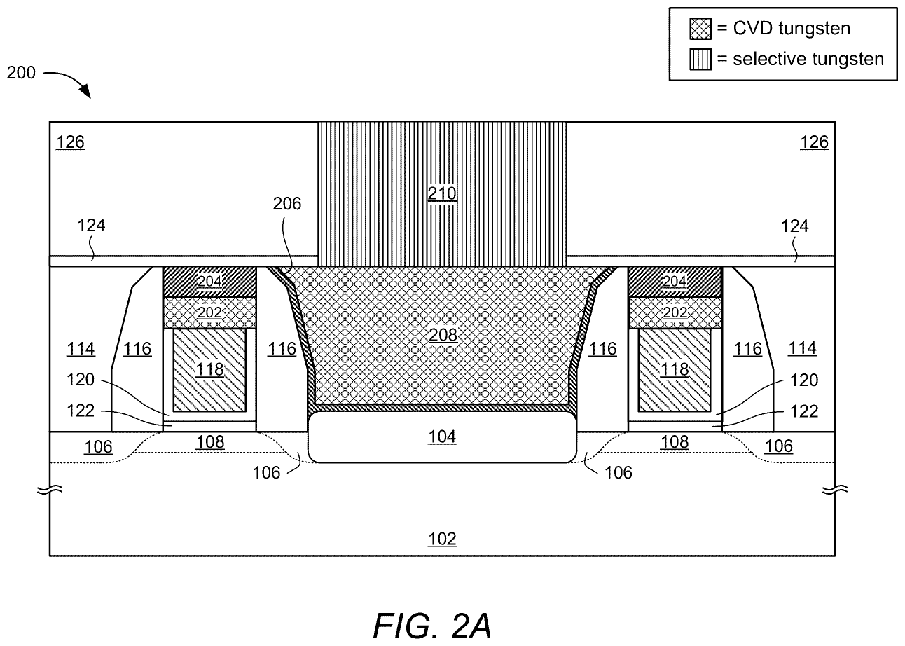

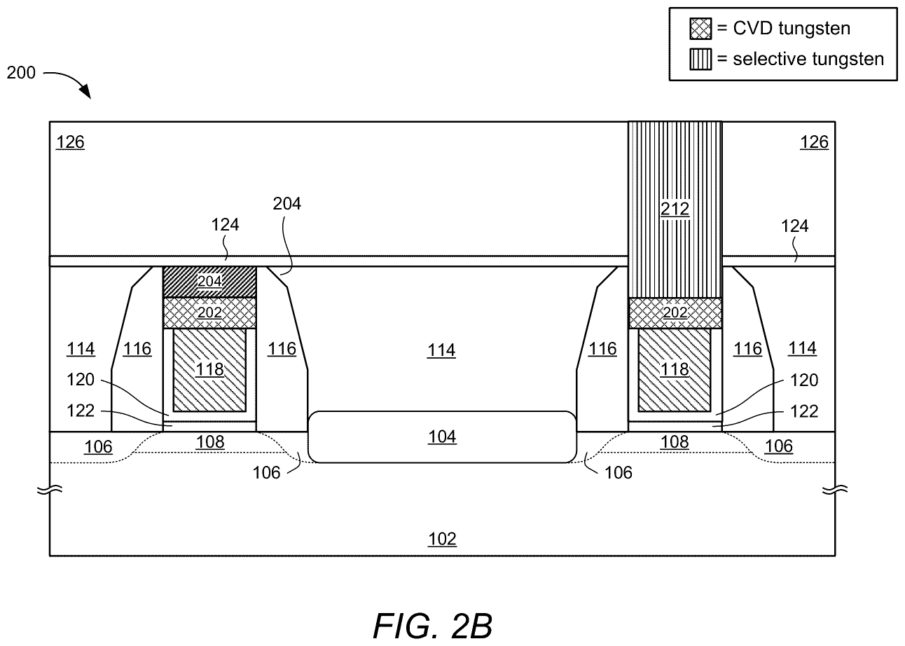

FIG. 2A and FIG. 2B illustrate two different cross-sectional views of an example 200 of a selective tungsten contact plug structure above gate and source/drain contacts, according to aspects of the disclosure. As explained below, FIGS. 2A and 2B show different cross-sectional views from the one shown in FIG. 1. However, the epitaxial structure 104, S/D region 106, channel region 108, passivation material 114, gate spacers 116, metal gate 118, high-k material 120, interfacial layer 122, dielectric etch stop layer 124, and upper passivation layer 126 are substantially architecturally similar to their like-numbered elements in FIG. 1, and therefore their descriptions are not repeated here, except that, in FIG. 2A and FIG. 2B, the metal gate 118 may comprise titanium nitride (TiN) or titanium aluminum carbon (TiAlC).

For clarity, FIG. 2A shows a cross-sectional view of a portion of the circuit that has only a S/D contract but not a gate contact. As shown in FIG. 2A, the gate structures include an additional metal cap 202 topped with a dielectric layer 204. In some aspects, the metal cap 202 is deposited using a CVD process. In some aspects, the metal cap 202 may be tungsten or cobalt. In some aspects, the dielectric layer 204 may be silicon nitride (SiN).

Once this self-aligned gate structure is fabricated, this structure allows subsequent fabrication of a large, self-aligned S/D contact comprising an S/D contact barrier layer 206 and a tungsten or cobalt contact 208, to achieve minimal S/D contact resistance. The self-aligned process allows the S/D contact structure to fill the space between the gate spacers 116. In some aspects, the S/D contact barrier layer 206 is in physical contact with the gate spacers 116. As shown in FIG. 2A, the S/D contact may include a selective, barrierless tungsten plug 210 for electrical connection to metal interconnection layers above the upper passivation layer 126. In some aspects, the selective, barrierless tungsten plug 210 is formed by selective CVD on metallic surfaces.

For clarity, FIG. 2B shows a cross-sectional view of a portion of the circuit that has only a gate contact but not a S/D contact. FIG. 2B shows the gate contact in more detail. The gate contact includes a contact plug 212 comprising selective barrierless tungsten that was grown on top of the metal cap 202 after the dielectric layer 204 was removed. In some aspects, the selective, barrierless tungsten plug 212 is formed by selective CVD on metallic surfaces. Because no gate contact barrier layer 132 is needed, the gate contact structure shown in FIG. 2B (i.e., contact plug 212 and metal cap 202) have lower resistance than the gate contact structure shown in FIG. 1. Because the self-aligned S/D contact structure can fill the space between the gate spacers 116, the S/D contact resistance can be minimized. Thus, the circuit in example 200 will have better performance than the circuit shown in example 100, because of the reduced S/D contact resistance and the reduced gate contact resistance. It will be understood that, although the S/D contact is shown only in FIG. 2A and the gate contact is shown only in FIG. 2B, they may both coexist within the same device.

In order to fully illustrate aspects of the design of the present disclosure, methods of fabrication are presented. Other methods of fabrication are possible, and discussed fabrication methods are presented only to aid understanding of the concepts disclosed herein.

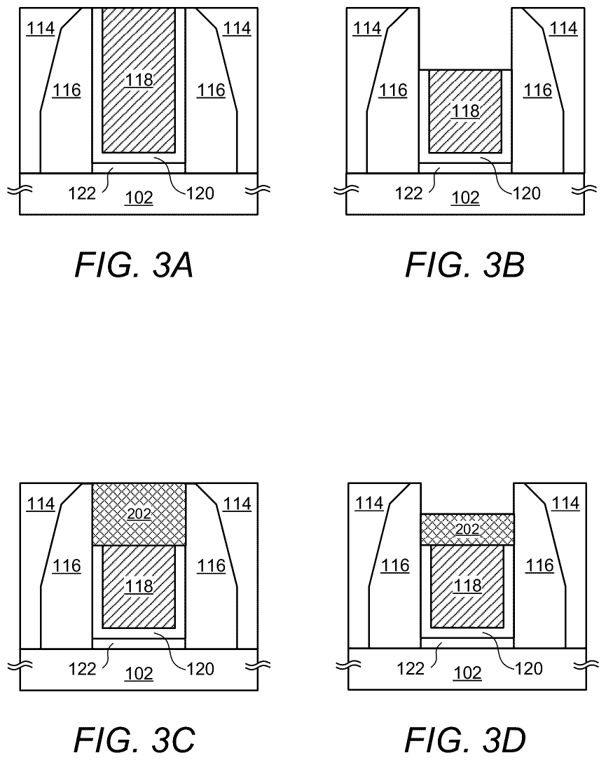

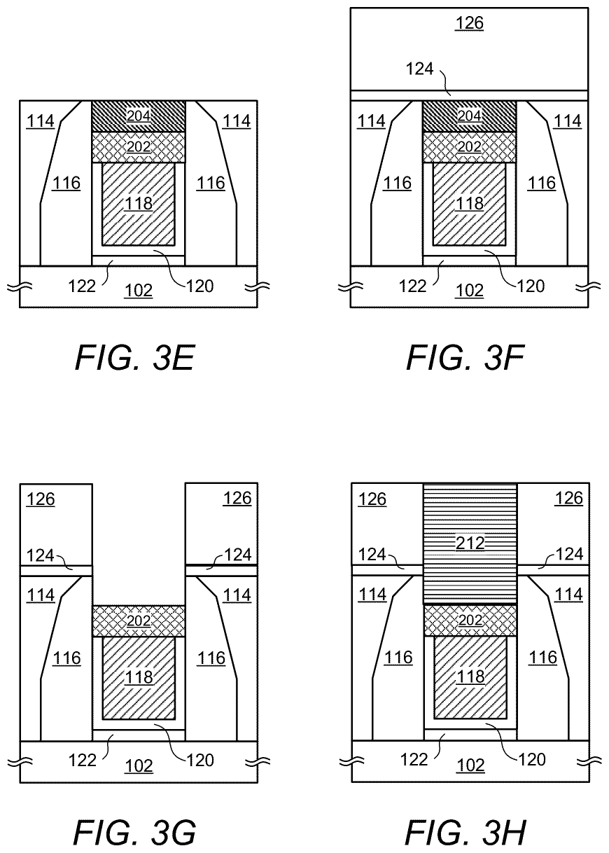

FIGS. 3A through 3H are cross-sectional views illustrating fabrication techniques in accordance with one or more aspects of the disclosure. The passivation material 114, gate spacers 116, metal gate 118, high-k material 120, interfacial layer 122, dielectric etch stop layer 124, and upper passivation layer 126 are substantially similar to their like-numbered elements in FIG. 1, and the metal cap 202, dielectric layer 204, and contact plug 212 are substantially similar to their like-numbered elements in FIG. 2, and therefore their descriptions are not repeated here.

FIG. 3A shows a cross-sectional view of a transistor having gate spacers 116 surrounding a gate structure comprising a metal gate 118, high-k material 120, and interfacial layer 122, such as may be created using a conventional wafer process, e.g., by depositing the high-k material 120 and the metal gate 118, and planarizing, e.g., with a chemical/mechanical planarization (CMP) process.

FIG. 3B shows a cross-sectional view of the transistor after an etching process to create a metal recess within the gate spacers 116, e.g., by etching away the metal gate 118 and high-k material 120 to a desired depth.

FIG. 3C shows a cross-sectional view of the transistor after depositing a metal cap 202 and then planarizing, e.g., with a CMP process. In some aspects, the metal cap 202 may be tungsten or cobalt.

FIG. 3D shows a cross-sectional view of the transistor after an etching process to create a metal recess within the gate spacers 116, e.g., by etching away the metal cap 202 to a desired depth.

FIG. 3E shows a cross-sectional view of the transistor after depositing a dielectric layer 204 and then planarizing with a CMP process. In some aspects, the dielectric layer 204 may comprise SiN. In some aspects, the dielectric layer 204 may be deposited using a CVD process. The SiN dielectric layer 204 makes it possible to form a self-aligned contact on the source and drain epitaxial layers, such as is shown in FIG. 2A.

FIG. 3F shows a cross-sectional view of the transistor after depositing a dielectric etch stop layer 124 and an upper passivation layer 126. In some aspects, the dielectric etch stop layer 124 may comprise silicon oxycarbide (SiOC). In some aspects, the upper passivation layer 126 may comprise SiO₂.

FIG. 3G shows a cross-sectional view of the transistor after an etching process to create a contact hole through the upper passivation layer 126, the dielectric etch stop layer 124, and the dielectric layer 204, until the metal cap 202 is exposed.

FIG. 3H shows a cross-sectional view of the transistor after selective tungsten growth to create a contact plug 212 above the metal cap 202, followed by planarization, e.g., with a CMP process. The resulting gate contact structure comprises the metal gate 118, the metal cap 202, and the contact plug 212, but does not include a gate contact barrier layer 132. Both the use of selective tungsten for the contact plug 212 and the lack of a barrier layer result in a lower gate contact resistance compared with the conventional gate contact structure illustrated in FIG. 1.

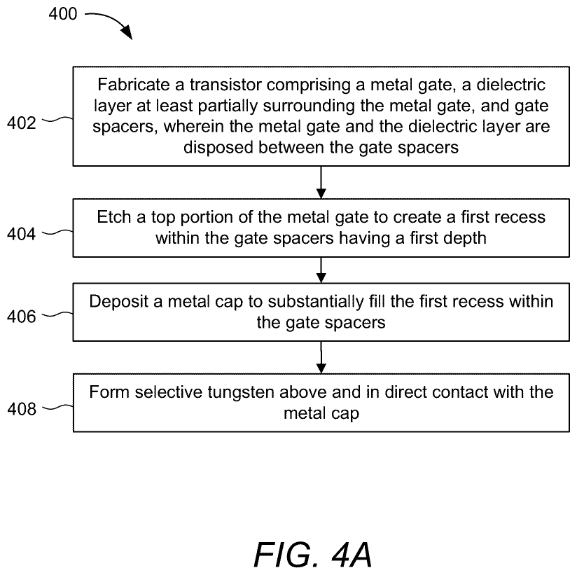

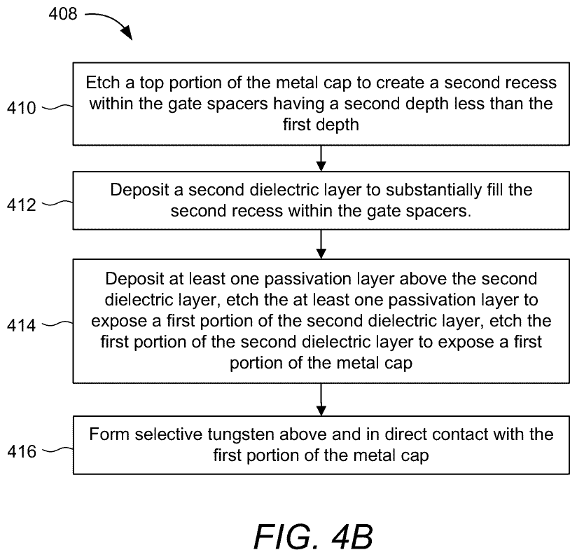

FIG. 4A and FIG. 4B are flowcharts showing portions of an example process 400 associated with selective tungsten contact plugs above gate contacts, according to aspects of the disclosure. It will be appreciated from the foregoing disclosure that additional processes for fabricating the various aspects disclosed herein will be apparent to those skilled in the art and a literal rendition of the processes discussed above will not be provided or illustrated in the included drawings. It will be appreciated that the sequence of the fabrication processes are not necessarily in any order and later processes may be discussed earlier to provide an example of the breadth of the various aspects disclosed.

As shown in FIG. 4A, process 400 may include, at block 402, fabricating a transistor comprising a metal gate, a dielectric layer at least partially surrounding the gate, and gate spacers, wherein the metal gate and the dielectric layer are disposed between the gate spacers.

As further shown in FIG. 4A, process 400 may include, at block 404, etching a top portion of the metal gate to create a first recess within the gate spacers having a first depth.

As further shown in FIG. 4A, process 400 may include, at block 406, depositing a metal cap to substantially fill the first recess within the gate spacers. In some aspects, depositing the metal cap comprises depositing tungsten or cobalt.

As further shown in FIG. 4A, process 400 may include, at block 408, forming selective tungsten above the first portion of the metal cap. Selective tungsten may be deposited above the metal cap directly, i.e., without the need for a barrier layer between the selective tungsten and the metal cap.

FIG. 4B shows an example implementation of block 408 in more detail. As shown in FIG. 4B, block 408 may include, at block 410, etching a top portion of the metal cap to create a second recess within the gate spacers having a second depth less than the first depth.

As further shown in FIG. 4B, block 408 may include, at block 412, depositing a second dielectric layer to substantially fill the second recess within the gate spacers. In some aspects, depositing the second dielectric layer comprises depositing silicon nitride (SiN).

As further shown in FIG. 4B, block 408 may include, at block 414, depositing at least one passivation layer above the second dielectric layer, etching the at least one passivation layer to expose a first portion of the second dielectric layer, and etching the first portion of the second dielectric layer to expose a first portion of the metal cap.

As further shown in FIG. 4B, block 408 may include, at block 416, forming selective tungsten above and in direct contact with the first portion of the metal cap.

In some aspects, process 400 includes depositing a source/drain (S/D) barrier layer above at least a portion of the source region or the drain region, and depositing an S/D contact above the S/D barrier layer, at least a portion of which comprising selective tungsten. In some aspects, depositing the S/D barrier layer comprises depositing titanium (Ti) or titanium nitride (TiN). In some aspects, depositing the S/D contact comprises depositing a first portion of the S/D contact using a CVD process and depositing a second portion of the S/D contact above the first portion of the S/D contact, the second portion of the S/D contact comprising selective tungsten.

Process 400 may include additional implementations, such as any single implementation or any combination of implementations described below and/or in connection with one or more other processes described elsewhere herein. Although FIGS. 4A and 4B show example blocks of process 400, in some implementations, process 400 may include additional blocks, fewer blocks, different blocks, or differently arranged blocks than those depicted in FIGS. 4A and 4B. Additionally, or alternatively, two or more of the blocks of process 400 may be performed in parallel.

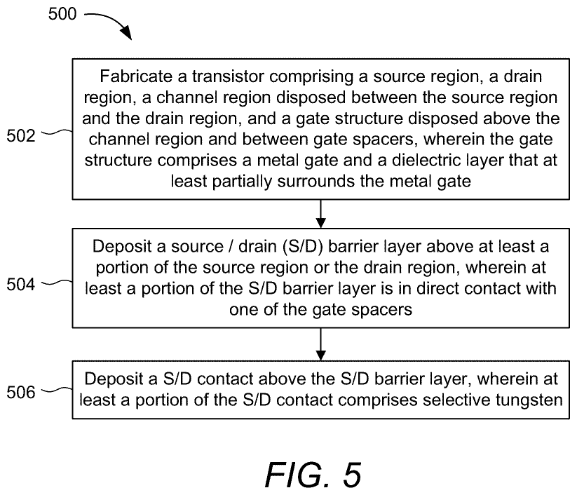

FIG. 5 is a flowchart showing an example process 500 associated with selective tungsten contact plugs above source/drain contacts, according to aspects of the disclosure. As shown in FIG. 5, process 500 may include, at block 502, fabricating a transistor comprising a source region, a drain region, a channel region disposed between the source region and the drain region, and a gate structure disposed above the channel region and between gate spacers, wherein the gate structure comprises a metal gate and a dielectric layer that at least partially surrounds the metal gate.

As further shown in FIG. 5, process 500 may include, at block 504, depositing a S/D barrier layer above at least a portion of the source region or the drain region, wherein at least a portion of the S/D barrier layer is in direct contact with one of the gate spacers.

As further shown in FIG. 5, process 500 may include, at block 506, depositing a S/D contact above the S/D barrier layer, wherein at least a portion of the S/D contact comprises selective tungsten.

In some aspects, the gate structures are fabricated before the S/D barrier layer is deposited. For example, after the gate structures are fabricated, they may be covered with a second dielectric layer may then be etched to expose the source and drain regions on the outside of the gate spacers and also the outside wall of each gate spacer (the inside wall of each gate spacer being in contact with the first dielectric layer that partially envelops the metal gate). Because the source and drain regions are exposed but the gate structures are not, the S/D barrier layer and the S/D contact material may be deposited in a self-aligned manner. Thus, the S/D contact structure presented herein may be referred to as a self-aligned S/D contact. The self-aligned nature allows the S/D contact to fill all of the available space from the contact point on the source or drain region to the outer wall of the gate spacers (or to the outer wall of one gate spacer, if the S/D contact is not between two transistors).

In some aspects, depositing the S/D barrier layer comprises depositing titanium (Ti) or titanium nitride (TiN).

In some aspects, depositing the S/D contact comprises depositing a first portion of the S/D contact using a chemical vapor deposition (CVD) process and depositing a second portion of the S/D contact above the first portion of the S/D contact, the second portion of the S/D contact comprising selective tungsten.

In some aspects, process 500 may further comprise, prior to depositing the S/D barrier layer, etching a top portion of the metal gate to create a first recess within the gate spacers having a first depth, depositing a metal cap to substantially fill the first recess within the gate spacers, etching a top portion of the metal cap to create a second recess within the gate spacers having a second depth less than the first depth, and depositing a second dielectric layer to substantially fill the second recess within the gate spacers.

In some aspects, process 500 may further comprise, after depositing the S/D contact, etching the second dielectric layer to expose the second recess within the gate spacers having a second depth less than the first depth, and forming selective tungsten at least within the second recess and in direct contact with the metal cap.

Process 500 may include additional implementations, such as any single implementation or any combination of implementations described below and/or in connection with one or more other processes described elsewhere herein. Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

In some aspects, process 400 and process 500 may include at least one chemical/mechanical planarization (CMP) step.

The gate and S/D contacts disclosed herein provide various technical advantages. Such technical advantages include, but are not limited to, the following: reduced gate resistance, at least in part due to the barrier-less structures disclosed herein and the use of selective tungsten rather than CVD tungsten for the gate contact plugs through passivation layers, and a self-aligning S/D contact with reduced resistance, at least in part due to the self-aligned process, which allows creation of larger S/D contacts (e.g., filling the space between one transistor's gate spacer and another transistor's gate spacer). Other technical advantages will be recognized from various aspects disclosed herein and these technical advantages are merely provided as examples and should not be construed to limit any of the various aspects disclosed herein.

The foregoing disclosed devices and functionalities may be designed and stored in computer files (e.g., register-transfer level (RTL), Geometric Data Stream (GDS) Gerber, and the like) stored on computer-readable media. Some or all such files may be provided to fabrication handlers who fabricate devices based on such files. Resulting products may include various components, including semiconductor wafers that are then cut into semiconductor die and packaged into semiconductor packages, integrated devices, package on package devices, system-on-chip devices, and the like, which may then be employed in the various devices described herein.

It will be appreciated that the foregoing fabrication process was provided merely as general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

The transistor and semiconductor structure described herein may be incorporated into a variety of devices. For example, the transistor may be part of an apparatus, such as a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, an access point, a base station, and a device in an automotive vehicle. In some aspects, the transistor or semiconductor structure may be part of a mobile device.

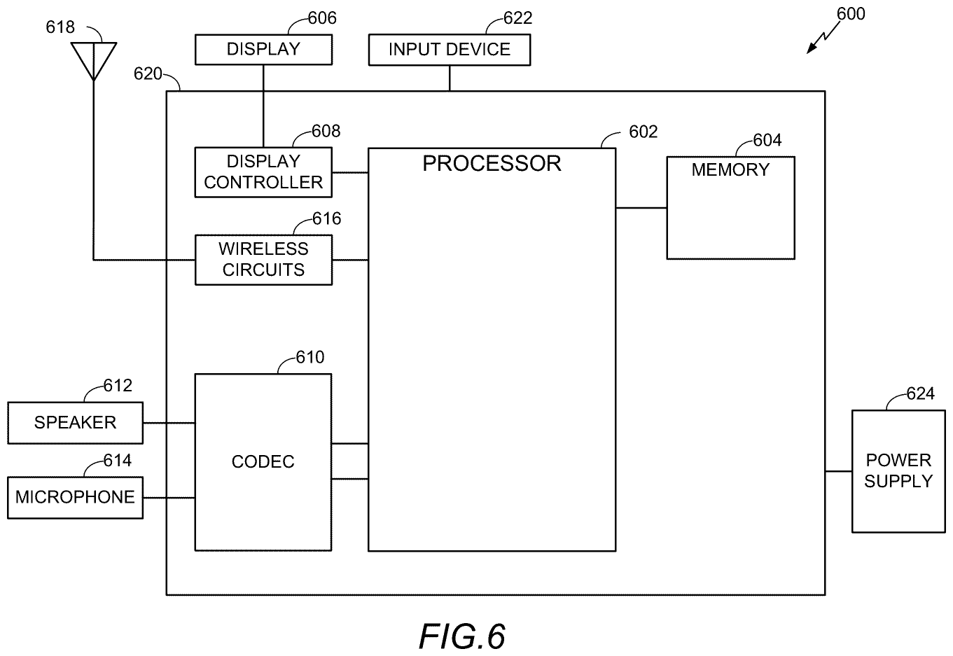

FIG. 6 illustrates an exemplary mobile device in accordance with some examples of the disclosure Referring now to FIG. 6, a block diagram of a mobile device that is configured according to exemplary aspects is depicted and generally designated mobile device 600. In some aspects, mobile device 600 may be configured as a wireless communication device. As shown, mobile device 600 includes processor 602. Processor 602 may be communicatively coupled to memory 604 over a link, which may be a die-to-die or chip-to-chip link. Mobile device 600 also includes display 606 and display controller 608, with display controller 608 coupled to processor 602 and to display 606.

In some aspects, FIG. 6 may include coder/decoder (CODEC) 610 (e.g., an audio and/or voice CODEC) coupled to processor 602; speaker 612 and microphone 614 coupled to CODEC 610; and wireless circuits 616 coupled to wireless antenna 618 and to processor 602.

In a particular aspect, where one or more of the above-mentioned blocks are present, processor 602, display controller 608, memory 604, CODEC 610, and wireless circuits 616 can be included in a system-in-package or system-on-chip (SoC) device 620. Input device 622 (e.g., physical or virtual keyboard), display 606, speaker 612, microphone 614, wireless antenna 618, and power supply 624 (e.g., battery) may be external to SoC device 620 and may be coupled to a component of SoC device 620, such as an interface or a controller. The selective tungsten contact plugs above gate and S/D contacts could be present in the processor 602, memory 604, or any other component within the SoC device 620, for example.

It should be noted that although FIG. 6 depicts a mobile device 600, processor 602 and memory 604 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

Other electronic devices may also feature processor 602 and memory 604 including, but not limited to, a group of devices (e.g., electronic devices) that includes hand-held personal communication systems (PCS) units, portable data units, global positioning system (GPS) enabled devices, wearable devices, servers, routers, electronic devices implemented in automotive vehicles (e.g., autonomous vehicles), an Internet of things (IoT) device or any other device that stores or retrieves data or computer instructions or any combination thereof.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage, or mode of operation. Furthermore, a particular feature and/or structure can be combined with one or more other features and/or structures.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer, or an electronic circuit. In some examples, some or a plurality of the most important method actions can be performed by such an apparatus.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an insulator and a conductor). Furthermore, it is also intended that aspects of a clause can be included in any other independent clause, even if the clause is not directly dependent on the independent clause.

Implementation examples are described in the following numbered clauses:
Clause 1. A transistor, comprising: a gate structure, comprising: a metal gate; a dielectric layer at least partially surrounding the metal gate; a metal cap disposed over a portion of the metal gate that is not surrounded by the dielectric layer; and a gate contact comprising tungsten, disposed over, and in direct contact with, the metal cap.
Clause 2. The transistor of clause 1, wherein the dielectric layer comprises a material with a dielectric constant greater than 3.9.
Clause 3. The transistor of clause 2, wherein the dielectric layer comprises hafnium oxide (HfO2).
Clause 4. The transistor of any of clauses 1 to 3, wherein the metal gate comprises titanium nitride (TiN) or titanium aluminum carbon (TiAlC).
Clause 5. The transistor of any of clauses 1 to 4, wherein the metal cap comprises tungsten or cobalt.
Clause 6. The transistor of any of clauses 1 to 5, wherein the metal gate and the dielectric layer are disposed between gate spacers and wherein the transistor further comprises: a source region; a drain region; and a S/D contact structure, the S/D contact structure comprising: an S/D barrier layer disposed above at least a portion of the source region or the drain region, wherein at least a portion of the S/D barrier layer is in direct contact with one of the gate spacers; and an S/D contact, comprising a first portion disposed above the S/D barrier layer, and a second portion comprising tungsten, disposed above the first portion, and in direct contact with the first portion.
Clause 7. The transistor of clause 6, wherein the S/D barrier layer comprises titanium (Ti) or titanium nitride (TiN).
Clause 8. The transistor of any of clauses 6 to 7, wherein the first portion of the S/D contact comprises tungsten or cobalt.
Clause 9. The transistor of any of clauses 1 to 8, wherein the transistor is part of an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, an access point, a base station, and a device in an automotive vehicle.
Clause 10. A semiconductor structure, comprising: a transistor, comprising: a source region; a drain region; a channel region, the channel region being disposed between the source region and the drain region; a gate structure disposed above the channel region, comprising a metal gate disposed between gate spacers; and a S/D contact structure, the S/D contact structure comprising: an S/D barrier layer disposed above at least a portion of the source region or the drain region, wherein at least a portion of the S/D barrier layer is in direct contact with one of the gate spacers; and an S/D contact, comprising a first portion disposed above the S/D barrier layer; and a second portion comprising tungsten, disposed above the first portion.
Clause 11. The semiconductor structure of clause 10, wherein the S/D barrier layer comprises titanium (Ti) or titanium nitride (TiN).
Clause 12. The semiconductor structure of any of clauses 10 to 11, wherein the first portion of the S/D contact comprises tungsten or cobalt.
Clause 13. A method of fabricating a gate contact structure for a transistor, the transistor comprising a metal gate, a dielectric layer at least partially surrounding the metal gate, and gate spacers, wherein the metal gate and the dielectric layer are disposed between the gate spacers, the method comprising: etching a top portion of the metal gate to create a first recess within the gate spacers having a first depth; depositing a metal cap to substantially fill the first recess within the gate spacers; and forming selective tungsten above and in direct contact with the metal cap.
Clause 14. The method of clause 13, wherein depositing the metal cap comprises depositing tungsten or cobalt.
Clause 15. The method of any of clauses 13 to 14, wherein forming selective tungsten above and in direct contact with the metal cap comprises: etching a top portion of the metal cap to create a second recess within the gate spacers having a second depth less than the first depth; and forming selective tungsten at least within the second recess and in direct contact with the metal cap.
Clause 16. A method of fabricating a S/D contact structure for a transistor comprising a source region, a drain region, a channel region disposed between the source region and the drain region, and a gate structure disposed above the channel region and between gate spacers, wherein the gate structure comprises a metal gate and a dielectric layer that at least partially surrounds the metal gate, the method comprising: depositing a S/D barrier layer above at least a portion of the source region or the drain region, wherein at least a portion of the S/D barrier layer is in direct contact with one of the gate spacers; and depositing an S/D contact above the S/D barrier layer, wherein at least a portion of the S/D contact comprises selective tungsten.
Clause 17. The method of clause 16, wherein depositing the S/D barrier layer comprises depositing titanium (Ti) or titanium nitride (TiN).
Clause 18. The method of any of clauses 16 to 17, wherein depositing the S/D contact comprises depositing a first portion of the S/D contact using a chemical vapor deposition (CVD) process and depositing a second portion of the S/D contact above the first portion of the S/D contact, the second portion of the S/D contact comprising selective tungsten.
Clause 19. The method of any of clauses 16 to 18, further comprising, prior to depositing the S/D barrier layer: etching a top portion of the metal gate to create a first recess within the gate spacers having a first depth; depositing a metal cap to substantially fill the first recess within the gate spacers; etching a top portion of the metal cap to create a second recess within the gate spacers having a second depth less than the first depth; and depositing a second dielectric layer to substantially fill the second recess within the gate spacers.
Clause 20. The method of clause 19, further comprising, after depositing the S/D contact; etching the second dielectric layer to expose the second recess within the gate spacers; and forming selective tungsten at least within the second recess and in direct contact with the metal cap.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A transistor, comprising:
a gate structure, comprising:
a metal gate;
a dielectric layer at least partially surrounding the metal gate;
a metal cap disposed over a portion of the metal gate that is not surrounded by the dielectric layer; and
a gate contact comprising tungsten, disposed over, and in direct contact with, the metal cap.

2. The transistor of claim 1, wherein the dielectric layer comprises a material with a dielectric constant greater than 3.9.

3. The transistor of claim 2, wherein the dielectric layer comprises hafnium oxide (HfO₂).

4. The transistor of claim 1, wherein the metal gate comprises titanium nitride (TiN) or titanium aluminum carbon (TiAlC).

5. The transistor of claim 1, wherein the metal cap comprises tungsten or cobalt.

6. The transistor of claim 1, wherein the metal gate and the dielectric layer are disposed between gate spacers and wherein the transistor further comprises:
a source region;
a drain region; and
a source or drain (S/D) contact structure, the S/D contact structure comprising:
an S/D barrier layer disposed above at least a portion of the source region or the drain region, wherein at least a portion of the S/D barrier layer is in direct contact with one of the gate spacers; and
an S/D contact, comprising a first portion disposed above the S/D barrier layer, and a second portion comprising tungsten, disposed above the first portion, and in direct contact with the first portion.

7. The transistor of claim 6, wherein the S/D barrier layer comprises titanium (Ti) or titanium nitride (TiN).

8. The transistor of claim 6, wherein the first portion of the S/D contact comprises tungsten or cobalt.

9. The transistor of claim 1, wherein the transistor is part of an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, an access point, a base station, and a device in an automotive vehicle.

10. A semiconductor structure, comprising:
a transistor, comprising:
a source region;
a drain region;
a channel region, the channel region being disposed between the source region and the drain region;
a gate structure disposed above the channel region, comprising a metal gate disposed between gate spacers; and
a source or drain (S/D) contact structure, the S/D contact structure comprising:
an S/D barrier layer disposed above at least a portion of the source region or the drain region, wherein at least a portion of the S/D barrier layer is in direct contact with one of the gate spacers; and
an S/D contact, comprising a first portion disposed above the S/D barrier layer; and a second portion comprising tungsten, disposed above the first portion.

11. The semiconductor structure of claim 10, wherein the S/D barrier layer comprises titanium (Ti) or titanium nitride (TiN).

12. The semiconductor structure of claim 10, wherein the first portion of the S/D contact comprises tungsten or cobalt.

13. A method of fabricating a gate contact structure for a transistor, the transistor comprising a metal gate, a dielectric layer at least partially surrounding the metal gate, and gate spacers, wherein the metal gate and the dielectric layer are disposed between the gate spacers, the method comprising:
etching a top portion of the metal gate to create a first recess within the gate spacers having a first depth;
depositing a metal cap to substantially fill the first recess within the gate spacers; and
forming selective tungsten above and in direct contact with the metal cap.

14. The method of claim 13, wherein depositing the metal cap comprises depositing tungsten or cobalt.

15. The method of claim 13, wherein forming selective tungsten above and in direct contact with the metal cap comprises:
etching a top portion of the metal cap to create a second recess within the gate spacers having a second depth less than the first depth; and
forming selective tungsten at least within the second recess and in direct contact with the metal cap.

16. A method of fabricating a source or drain (S/D) contact structure for a transistor comprising a source region, a drain region, a channel region disposed between the source region and the drain region, and a gate structure disposed above the channel region and between gate spacers, wherein the gate structure comprises a metal gate and a dielectric layer that at least partially surrounds the metal gate, the method comprising:
depositing a S/D barrier layer above at least a portion of the source region or the drain region, wherein at least a portion of the S/D barrier layer is in direct contact with one of the gate spacers; and
depositing an S/D contact above the S/D barrier layer, wherein at least a portion of the S/D contact comprises selective tungsten.

17. The method of claim 16, wherein depositing the S/D barrier layer comprises depositing titanium (Ti) or titanium nitride (TiN).

18. The method of claim 16, wherein depositing the S/D contact comprises depositing a first portion of the S/D contact using a chemical vapor deposition (CVD) process and depositing a second portion of the S/D contact above the first portion of the S/D contact, the second portion of the S/D contact comprising selective tungsten.

19. The method of claim 16, further comprising, prior to depositing the S/D barrier layer:
etching a top portion of the metal gate to create a first recess within the gate spacers having a first depth;
depositing a metal cap to substantially fill the first recess within the gate spacers;
etching a top portion of the metal cap to create a second recess within the gate spacers having a second depth less than the first depth; and
depositing a second dielectric layer to substantially fill the second recess within the gate spacers.

20. The method of claim 19, further comprising, after depositing the S/D contact:
etching the second dielectric layer to expose the second recess within the gate spacers; and
forming selective tungsten at least within the second recess and in direct contact with the metal cap.
